(19) United States
(12) Patent Application Publication
(10) Pub. No.: US 2025/0122367 A1
(43) Pub. Date: Apr. 17, 2025

(54) POLYMER COMPOSITE, USE THEREOF, LOW DIELECTRIC RESIN COMPOSITION, PREPREG, AND METAL FOIL LAMINATED BOARD

(71) Applicant: LCY CHEMICAL CORP., Kaohsiung City (TW)

(72) Inventors: Chi-Jui HSIEH, Kaohsiung City (TW); Tz-Jie JU, Kaohsiung City (TW); Yi-Hsuan TANG, Kaohsiung City (TW); Chiung Chi LIN, Kaohsiung City (TW); Hung Lin CHEN, Kaohsiung City (TW); Chi Yi LIU, Kaohsiung City (TW); Hsiao-Chu LIN, Kaohsiung City (TW); Ka Chun AU-YEUNG, Kaohsiung City (TW); Wei-Liang LEE, Kaohsiung City (TW); Yu-Chen HSU, Kaohsiung City (TW); Ming-Hung LIAO, Kaohsiung City (TW); Chien-Han CHEN, Kaohsiung City (TW); Yu-Tien CHEN, Kaohsiung City (TW); Yu-Pin LIN, Kaohsiung City (TW); Gang-Lun FAN, Kaohsiung City (TW)

(21) Appl. No.: 18/911,757

(22) Filed: Oct. 10, 2024

Related U.S. Application Data
(60) Provisional application No. 63/589,732, filed on Oct. 12, 2023.

(51) Int. Cl. C08L 25/08; C08J 5/24; C08L 45/00

(52) U.S. Cl. CPC C08L 25/08; C08J 5/244; C08L 45/00; C08J 2325/08; C08J 2345/00; C08J 2453/02

(57) ABSTRACT

A polymer composite for preparing a low dielectric resin composition having a dielectric loss tangent (Df) that is less than or equal to 0.00200 is provided. The polymer composite includes a first styrene-based copolymer having a weight average molecular weight that is lower than 20,000 g/mol and a second styrene-based copolymer having a weight average molecular weight that is higher than 20,000 g/mol, wherein the weight ratio of the first styrene-based copolymer to the second styrene-based copolymer is from 5/95 to 95/5.

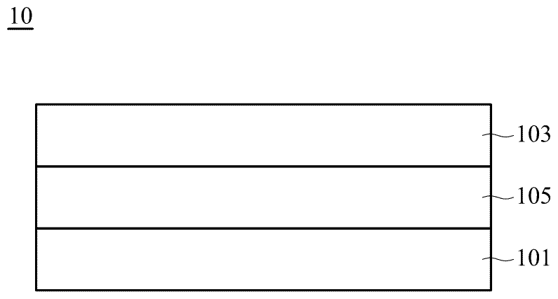

### CROSS REFERENCE TO RELATED APPLICATIONS

This application claims the benefit of U.S. Provisional Application No. 63/589,732 filed on Oct. 12, 2023, the entirety of which is incorporated by reference herein.

### BACKGROUND OF THE INVENTION

### Field of the Invention

The present invention relates to a polymer composite, the use thereof, a low dielectric resin composition, a prepreg, and a metal foil laminated board. In particular, the present invention relates to a polymer composite including two kinds of styrene-based copolymers, the use thereof, a low dielectric resin composition, a prepreg, and a metal foil laminated board.

### Description of the Related Art

5th generation (5G for short) mobile network technology is the latest generation of mobile communication technology. 5G mobile network technology has the characteristics of high-speed transmission, wide connection, and low latency. There are three types of 5G mobile communication technology, depending on the frequency band used: high-frequency 5G, intermediate-frequency 5G, and low-frequency 5G. High-frequency 5G can provide ultra-high connection rates.

However, in high-frequency 5G, the quality of signal transmission and reception will be affected by high-frequency path loss, conductor loss, and dielectric loss during the signal transmission and reception process. Therefore, it is necessary to develop a copper clad laminate (CCL) material having low dielectric loss to reduce the dielectric loss during the signal transmission and reception process in high-frequency 5G to improve the quality of signal transmission and reception.

The goal of reducing the dielectric loss can be achieved by reducing the dielectric properties (dielectric constant (Dk) and/or dielectric loss tangent (Df)) of the metal foil substrate material. Beyond the need for dielectric properties, the typical composition also encounters difficulties in processability and fluidity. This poor flowability results in inadequate filling performance, rendering the product unusable. Therefore, a material and its resin composition having lower dielectric losses and better processing performance is still being sought.

### BRIEF SUMMARY OF THE INVENTION

In view of the above problems, the disclosure provides a polymer composite for preparing a low dielectric resin composition having a low dielectric loss tangent (Df), a low dielectric resin composition including the same, a prepreg manufactured from the low dielectric resin composition, and a metal foil laminated board including the prepreg.

An embodiment of the disclosure provides a polymer composite for preparing a low dielectric resin composition having a dielectric loss tangent (Df) that is less than or equal to 0.00200. The polymer composite includes a first styrene-based copolymer having a weight average molecular weight that is lower than 20,000 g/mol and a second styrene-based copolymer having a weight average molecular weight that is higher than 20,000 g/mol, wherein the weight ratio of the first styrene-based copolymer to the second styrene-based copolymer is from 5/95 to 95/5.

An embodiment of the disclosure provides a polymer composite for preparing a low dielectric resin composition having a dielectric loss tangent (Df) that is less than or equal to 0.00200. The polymer composite includes a first styrene-based copolymer, which is liquid at 25° C. and a second styrene-based copolymer, which is solid at 25° C., wherein the weight ratio of the first styrene-based copolymer to the second styrene-based copolymer is from 5/95 to 95/5.

An embodiment of the disclosure provides a method of using a polymer composite, comprising: using the polymer composite to form a mixture including hydrocarbon resin for manufacturing a metal foil laminated board having a dielectric loss tangent (Df) that is less than or equal to 0.00200. The polymer composite includes a first styrene-based copolymer having a weight average molecular weight that is lower than 20,000 g/mol and a second styrene-based copolymer having a weight average molecular weight that is higher than 20,000 g/mol, wherein the weight ratio of the first styrene-based copolymer to the second styrene-based copolymer is from 5/95 to 95/5.

An embodiment of the disclosure provides a low dielectric resin composition. The low dielectric resin composition includes a first styrene-based copolymer having a weight average molecular weight that is lower than 20,000 g/mol, and a second styrene-based copolymer having a weight average molecular weight that is higher than 20,000 g/mol, wherein the weight ratio of the first styrene-based copolymer to the second styrene-based copolymer is from 5/95 to 95/5, and the low dielectric resin composition has a dielectric loss tangent (Df) that is less than or equal to 0.00200.

An embodiment of the disclosure provides a low dielectric resin composition. The low dielectric resin composition includes a first styrene-based copolymer, which is liquid at 25° C. and a second styrene-based copolymer, which is solid at 25° C., wherein the weight ratio of the first styrene-based copolymer to the second styrene-based copolymer is from 5/95 to 95/5, and the low dielectric resin composition has a dielectric loss tangent (Df) that is less than or equal to 0.00200.

An embodiment of the disclosure provides a low dielectric resin composition. The low dielectric resin composition includes a hydrocarbon resin, a first styrene-based copolymer having a weight average molecular weight that is lower than 20,000 g/mol and a second styrene-based copolymer having a weight average molecular weight that is higher than 20,000 g/mol.

An embodiment of the disclosure provides a low dielectric resin composition. The low dielectric resin composition includes a hydrocarbon resin, a first styrene-based copolymer, which is liquid at 25° C. and a second styrene-based copolymer, which is solid at 25° C.

An embodiment of the disclosure provides a prepreg manufactured from a low dielectric resin composition including a polymer composite. The polymer composite includes a first styrene-based copolymer having a weight average molecular weight that is lower than 20,000 g/mol and a second styrene-based copolymer having a weight average molecular weight that is higher than 20,000 g/mol, wherein the weight ratio of the first styrene-based copolymer to the second styrene-based copolymer is from 5/95 to 95/5.

An embodiment of the disclosure provides a prepreg manufactured from a low dielectric resin composition including a polymer composite. The polymer composite includes a first styrene-based copolymer, which is liquid at 25° C. and a second styrene-based copolymer, which is solid at 25° C., wherein the weight ratio of the first styrene-based copolymer to the second styrene-based copolymer is from 5/95 to 95/5.

An embodiment of the disclosure provides a prepreg manufactured from a low dielectric resin composition. The low dielectric resin composition includes a hydrocarbon resin, a first styrene-based copolymer having a weight average molecular weight that is lower than 20,000 g/mol and a second styrene-based copolymer having a weight average molecular weight that is higher than 20,000 g/mol.

An embodiment of the disclosure provides a prepreg manufactured from a low dielectric resin composition. The low dielectric resin composition includes a hydrocarbon resin, a first styrene-based copolymer, which is liquid at 25° C. and a second styrene-based copolymer, which is solid at 25° C.

An embodiment of the disclosure provides a metal foil laminated board. The metal foil laminated board includes a prepreg manufactured from a low dielectric resin composition including a polymer composite. The polymer composite includes a first styrene-based copolymer having a weight average molecular weight that is lower than 20,000 g/mol and a second styrene-based copolymer having a weight average molecular weight that is higher than 20,000 g/mol, wherein the weight ratio of the first styrene-based copolymer to the second styrene-based copolymer is from 5/95 to 95/5.

An embodiment of the disclosure provides a metal foil laminated board. The metal foil laminated board includes a prepreg manufactured from a low dielectric resin composition including a polymer composite. The polymer composite includes a first styrene-based copolymer, which is liquid at 25° C. and a second styrene-based copolymer, which is solid at 25° C., wherein the weight ratio of the first styrene-based copolymer to the second styrene-based copolymer is from 5/95 to 95/5.

An embodiment of the disclosure provides a metal foil laminated board. The metal foil laminated board includes a prepreg manufactured from a low dielectric resin composition. The low dielectric resin composition includes a hydrocarbon resin, a first styrene-based copolymer having a weight average molecular weight that is lower than 20,000 g/mol and a second styrene-based copolymer having a weight average molecular weight that is higher than 20,000 g/mol.

An embodiment of the disclosure provides a metal foil laminated board. The metal foil laminated board includes a prepreg manufactured from a low dielectric resin composition. The low dielectric resin composition includes a hydrocarbon resin, a first styrene-based copolymer, which is liquid at 25° C. and a second styrene-based copolymer, which is solid at 25° C.

### BRIEF DESCRIPTION OF THE DRAWINGS

The present invention can be more fully understood by reading the subsequent detailed description and examples with references made to the accompanying drawings, wherein:

FIGURE is a schematic diagram of a metal foil laminated board in according to an embodiment of the disclosure.

### DETAILED DESCRIPTION OF THE INVENTION

It will be further understood that the terms “comprises,” and/or “includes” when used herein, specify the presence of stated features, integers, steps, operations, elements, components and/or groups thereof, but do not preclude the presence or addition of one or more other features, integers, steps, operations, elements, components and/or groups thereof. As used herein, the singular forms “a,” “an” and “the” are intended to include the plural forms as well, unless the context clearly indicates otherwise.

It will be understood that, although the terms first, second, etc. are be used herein to describe various elements, components, regions, layers and/or portions, these elements, components, regions, layers and/or portions should not be limited by these terms. These terms are used to distinguish one elements, components, regions, layers or portions from another elements, components, regions, layers or portions, but not to imply a required sequence of elements.

It will be understood that, the term “about”, “approximate”, “rough” as used herein usually indicates a value of a given value or range that varies within 20%, preferably within 10%, and preferably within 5%, or within 3%, or within 2%, or within 1%, or within 0.5%. The value given here are approximate value, i.e., “about”, “approximate”, or “rough” may be implied without specifying “about”, “approximate”, or “rough”. It will be further understood that the values indicated in herein may include the said values as well as deviation values that are within an acceptable deviation range for people having general knowledge in art. It will be understood that the expression “a-b” or “a to b” used herein to indicate a specific range of values is defined as “≥a and ≤b”.

Unless otherwise defined, all terms (including technical and scientific terms) used herein have the same meaning as commonly understood by a person skilled in the art to which the invention pertains. It will be further understood that terms, such as those defined in commonly used dictionaries, should be interpreted as having a meaning consistent with the relevant technology and the context or background of this disclosure and will not be interpreted in an idealized or overly formal sense unless expressly so defined herein. Descriptions of known functions and constructions that may unnecessarily obscure the present disclosure will be omitted below.

The term “C₁₋₂₀ alkyl group” used herein refers to a linear, branched, or cyclic aliphatic hydrocarbon monovalent group having 1 to 20 carbon atoms in the main carbon chain. The term “C₁₋₄ alkyl group” used herein refers to a linear, branched, or cyclic aliphatic hydrocarbon monovalent group having 1 to 4 carbon atoms in the main carbon chain. Examples of the C₁₋₂₀ alkyl group include, but are not limited to, a methyl group, an ethyl group, a propyl group, an iso-butyl group, a sec-butyl group, a tert-butyl group, a pentyl group, an iso-amyl group, a hexyl group, a decyl group, a dodecyl group, a cyclohexyl group, a cyclooctyl group, and a cyclododecyl group. Examples of the C₁₋₄ alkyl group include, but are not limited to, a methyl group, an ethyl group, and a propyl group.

The term “C₂₋₂₀ alkenyl group” used herein refers to a linear, branched, or cyclic aliphatic hydrocarbon monovalent group having 2 to 20 carbon atoms and at least one carbon-carbon double bond in the main carbon chain. Examples of the C₂₋₂₀ alkenyl group include, but are not limited to, an ethenyl group, a propenyl group, an isobutenyl group, a sec-butenyl group, a tert-butenyl group, apentenyl group, an isopentenyl group, a hexenyl group, a decenyl group, a dodecenyl group, a pentadecenyl group, a cyclohexenyl group, a cyclooctenyl group, a cyclopentenyl group, a cyclopentadienyl group, and a cyclopentadecenyl group.

The term “carboxylate group having C₁₋₂₀ alkyl chain group” used herein refers to a group having a structure of:

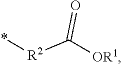

in which “*” represents a connecting site that connects other groups, R¹ represents a C₁₋₂₀ alkyl group, R² represents a single bond or a C₁₋₂₀ alkyl group, and the sum of the number of carbon atoms in the main carbon chain of the alkyl groups of R¹ and R² is 1-20.

An embodiment of the disclosure provides a polymer composite for preparing a low dielectric resin composition having a dielectric loss tangent (Df) that is less than or equal to 0.00200. The polymer composite includes a first styrene-based copolymer and a second styrene-based copolymer different from the first styrene-based copolymer, wherein the weight ratio of the first styrene-based copolymer to the second styrene-based copolymer is from 5/95 to 95/5. In some embodiments, the weight ratio of the first styrene-based copolymer to the second styrene-based copolymer may be within a range of 10/90 to 90/10, of 20/80 to 80/20, or of 25/75 to 80/20. In some embodiments, the weight ratio of the first styrene-based copolymer to the second styrene-based copolymer may be 5/95, 10/90, 15/85, 20/80, 25/75, 30/70, 35/65, 40/60, 45/55, 50/50, 55/45, 60/40, 65/35, 70/30, 75/25, 80/20, 85/15, 90/10, or 95/5, but the present disclosure is not limited thereto.

In some embodiments, the first styrene-based copolymer has a weight average molecular weight that is lower than 20,000 g/mol and the second styrene-based copolymer has a weight average molecular weight that is higher than 20,000 g/mol, but the present disclosure is not limited thereto. In some embodiments, the first styrene-based copolymer is liquid at 25° C., and the second styrene-based copolymer is solid at 25° C.

In the embodiments where the first styrene-based copolymer has a weight average molecular weight that is lower than 20,000 g/mol and the second styrene-based copolymer has a weight average molecular weight that is higher than 20,000 g/mol, the molecular weight of the first styrene-based copolymer is determined by a gel permeation chromatography (GPC). In some embodiments, the first styrene-based copolymer may have a weight average molecular weight that is lower than 10,000 g/mol, providing the improvement of processability and fluidity during copper-clad laminated board (CCL) manufacturing process. In some embodiments, the first styrene-based copolymer may have a weight average molecular weight within a range of higher than or equal to 5,000 g/mol and lower than 10,000 g/mol. In some embodiments, the first styrene-based copolymer may have a weight average molecular weight within a range of 5,000 g/mol to 9,000 g/mol, of 5,000 g/mol to 8,000 g/mol, of 5,000 g/mol to 7,000 g/mol, or of 5,000 g/mol to 6,000 g/mol. In some embodiments, the first styrene-based copolymer may have a weight average molecular weight within a range of 5,000 g/mol to 8,000 g/mol.

In the embodiments where the first styrene-based copolymer is liquid at 25° C. and the second styrene-based copolymer is solid at 25° C., the first styrene-based copolymer may have a weight average molecular weight that is lower than 20,000 g/mol. In some embodiments, the first styrene-based copolymer may have a weight average molecular weight that is lower than 10,000 g/mol, providing the improvement of processability and fluidity during copper-clad laminated board (CCL) manufacturing process. In some embodiments, the first styrene-based copolymer may have a weight average molecular weight within a range of higher than or equal to 5,000 g/mol and lower than 10,000 g/mol. In some embodiments, the first styrene-based copolymer may have a weight average molecular weight within a range of 5,000 g/mol to 9,000 g/mol, of 5,000 g/mol to 8,000 g/mol, of 5,000 g/mol to 7,000 g/mol, or of 5,000 g/mol to 6,000 g/mol. In some embodiments, the first styrene-based copolymer may have a weight average molecular weight within a range of 5,000 g/mol to 8,000 g/mol.

In some embodiments of the present disclosure, the first styrene-based copolymer has a polydispersity index (PDI) in a range of 1.0 to 1.1, wherein the polydispersity index (PDI) is determined by a gel permeation chromatography (GPC).

The first styrene-based copolymer may have a styrene block (as a hard segment) and a soft segment. The hard segment provides higher Tg and contributes strength, hardness and elevated temperature performance of the first styrene-based copolymer. The soft segment has some functional groups (such as vinyl group) for curing and contributes to the elasticity, toughness and resilience of the first styrene-based copolymer. In some embodiments, the first styrene-based copolymer may include 10-90 wt % of the hard segment and 90-10 wt % of the soft segment based on the total weight of the first styrene-based copolymer being 100 wt %. An example of the soft segment is the butadiene block, isoprene block, but the present disclosure is not limited thereto.

In the embodiments where the first styrene-based copolymer includes a butadiene block as a soft segment and a styrene block, the weight ratio of the styrene block to the butadiene block may be 10:90 to 90:10. In some embodiments, the weight ratio of the styrene block to the butadiene block may be 10:90 to 80:20, 10:90 to 70:30, 10:90 to 60:40, or 10:90 to 50:50, but the present disclosure is not limited thereto. In some embodiments, the weight ratio of the styrene block to the butadiene block is 10:90 to 50:50. In the present disclosure, the weight ratio of the styrene block to the butadiene block mentioned above is determined by a proton nuclear magnetic resonance (1H-NMR) method.

The butadiene block may include only a 1,2-bonding structure represented by formula (1), or include a 1,2-bonding structure represented by formula (1) and a 1,4-bonding structure represented by formula (2).

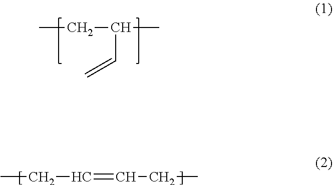

In some embodiments, in the butadiene block, the molar ratio of the 1,2-bonding structure represented by formula (1) to the 1,4-bonding structure represented by formula (2) may be 50:50 to 100:0. In the embodiments where the first styrene-based copolymer has a molar ratio of the 1,2-bonding structure represented by formula (1) to the 1,4-bonding structure represented by formula (2) in the range mentioned above, the first styrene-based copolymer has a high cure density. Therefore, the first styrene-based copolymer may have improved thermal properties. In some embodiments, in the butadiene block, the molar ratio of the 1,2-bonding structure represented by formula (1) to the 1,4-bonding structure represented by formula (2) may be 3:1 to 99:1. In some embodiments, in the butadiene block, the molar ratio of the 1,2-bonding structure represented by formula (1) to the 1,4-bonding structure represented by formula (2) may be 3:1 to 7:1, providing superior thermal performance. In some embodiments, the first styrene-based copolymer is a styrene-butadiene-styrene tri-block copolymer (SBS), and in the butadiene block, the molar ratio of the 1,2-bonding structure represented by formula (1) to the 1,4-bonding structure represented by formula (2) may be 5:1 to 7:1. In the present disclosure, the molar ratio of formula (1) and formula (2) is determined by a proton nuclear magnetic resonance (1H-NMR) method.

The first styrene-based copolymer may be a styrene block copolymer or a styrene random copolymer. In some embodiments, the first styrene-based copolymer is a styrene block copolymer which has less than 50 wt % of randomized comonomer repeat units based on the total weight of the first styrene block copolymer being 100 wt %, providing superior electrical performance. In some embodiments, the first styrene-based copolymer may be a styrene block copolymer selected from a group consisting of a styrene-butadiene block copolymer (SB), a styrene-butadiene-styrene tri-block copolymer (SBS), a butadiene-styrene-butadiene tri-block copolymer (BSB), and any combinations thereof, but the present disclosure is not limited thereto. In some embodiments, the first styrene-based copolymer may be a styrene-butadiene-styrene tri-block copolymer (SBS) or styrene-butadiene di-block copolymer (SB). In some embodiments, the first styrene-based copolymer may be a styrene-butadiene-styrene tri-block copolymer (SBS). In some embodiments, the first styrene-based copolymer may be a styrene-butadiene-styrene tri-block copolymer (SBS) that is liquid at 25° C.

In some embodiments, in the embodiments where the first styrene-based copolymer is a styrene-butadiene-styrene tri-block copolymer (SBS), the molar ratio of the 1,2-bonding structure represented by formula (1) to the 1,4-bonding structure represented by formula (2) in butadiene blocks of the styrene-butadiene-styrene tri-block copolymer (SBS) may be 3:1 to 7:1.

In some embodiments, the first styrene-based copolymer may be produced using the method described in Japanese unexamined Patent Application Publication No. 1994-192502, Japanese unexamined Patent Application Publication No. 2000-514122, or Japanese unexamined Patent Application Publication No. 2007-302901, but the present disclosure is not limited thereto. In some embodiments, the first styrene-based copolymer may be produced by a first styrene-based copolymer preparation method. The first styrene-based copolymer preparation method may include the following steps: introducing first styrene monomers and reacting the first styrene monomers into first styrene blocks; introducing butadiene monomers and reacting the butadiene monomers into butadiene blocks which are bonded to the first styrene blocks; optional introducing second styrene monomers and reacting the second styrene monomers into second styrene blocks which are bonded to the butadiene blocks. In some embodiments, the first styrene-based copolymer preparation method may further include purifying the first styrene monomers, the second styrene monomers, and the butadiene monomers under an inert atmosphere before the introductions thereof. In some embodiments, the first styrene-based copolymer preparation method may further include a termination step after a first styrene-based copolymer having a desired weight average molecular weight is obtained.

The first styrene-based copolymer mentioned above has high fluidity. Therefore, a processability of a polymer composite including the same can be improved. Additionally, short molecular chains of the first styrene-based copolymer can act as buffers during impact, increasing a toughening effect of a product made from a polymer composite including the same.

In the embodiments where the first styrene-based copolymer has a weight average molecular weight that is lower than 20,000 g/mol and the second styrene-based copolymer has a weight average molecular weight that is higher than 20,000 g/mol, the molecular weight of the second styrene-based copolymer is determined by a gel permeation chromatography (GPC). In some embodiments, the second styrene-based copolymer may have a weight average molecular weight that is in a range of higher than 20,000 g/mol and lower than 80,000 g/mol. In some embodiments, the second styrene-based copolymer may have a weight average molecular weight within a range of 40,000 g/mol to 78,000 g/mol, of 40,000 g/mol to 60,000 g/mol, of 40,000 g/mol to 70,000 g/mol, or of 40,000 g/mol to 50,000 g/mol. In some embodiments, the second styrene-based copolymer may have a weight average molecular weight within a range of 40,000 g/mol to 60,000 g/mol.

In the embodiments where the first styrene-based copolymer is liquid at 25° C. and the second styrene-based copolymer is solid at 25° C., the second styrene-based copolymer may have a weight average molecular weight that is higher than 20,000 g/mol. In some embodiments, the second styrene-based copolymer may have a weight average molecular weight that is in a range of higher than 20,000 g/mol and lower than 80,000 g/mol. In some embodiments, the second styrene-based copolymer may have a weight average molecular weight within a range of 40,000 g/mol to 78,000 g/mol, of 40,000 g/mol to 70,000 g/mol, of 40,000 g/mol to 60,000 g/mol, or of 40,000 g/mol to 50,000 g/mol. In some embodiments, the second styrene-based copolymer may have a weight average molecular weight within a range of 40,000 g/mol to 60,000 g/mol.

The second styrene-based copolymer may have a styrene block (as a hard segment) and a soft segment. The hard segment provides higher Tg and contributes strength, hardness and elevated temperature performance of the second styrene-based copolymer. The soft segment has some functional groups (such as vinyl group) for curing and contributes to the elasticity, toughness and resilience of the second styrene-based copolymer. In some embodiments, the second styrene-based copolymer may include 10-90 wt % of the hard segment and 90-10 wt % of the soft segment based on the total weight of the second styrene-based copolymer being 100 wt %. One example of the soft segment is the butadiene block, isoprene block, but the present disclosure is not limited thereto.

In the embodiments where the second styrene-based copolymer includes a butadiene block as a soft segment and a styrene block as a hard segment, the weight ratio of the styrene block to the butadiene block may be 10:90 to 90:10. In some embodiments, the weight ratio of the styrene block to the butadiene block may be 10:90 to 80:20, 10:90 to 70:30, 10:90 to 60:40, 20:80 to 80:20, 30:70 to 80:20, or 40:60 to 80:20, but the present disclosure is not limited thereto. In some embodiments, the weight ratio of the styrene block to the butadiene block is 10:90 to 50:50. In the present disclosure, the weight ratio of the styrene block to the butadiene block mentioned above is determined by a proton nuclear magnetic resonance (¹H-NMR) method.

In the embodiments where the second styrene-based copolymer includes a butadiene block as a soft segment, the butadiene block may include only a 1,2-bonding structure represented by formula (1) above, or include a 1,2-bonding structure represented by formula (1) and a 1,4-bonding structure represented by formula (2) above.

In some embodiments, in the butadiene block, the molar ratio of the 1,2-bonding structure represented by formula (1) to the 1,4-bonding structure represented by formula (2) may be 50:50 to 100:0. In the embodiments where the second styrene-based copolymer has a molar ratio of the 1,2-bonding structure represented by formula (1) to the 1,4-bonding structure represented by formula (2) in the range mentioned above, the second styrene-based copolymer has a high cure density. Therefore, the second styrene-based copolymer may have improved thermal properties. In some embodiments, in the butadiene block, the molar ratio of the 1,2-bonding structure represented by formula (1) to the 1,4-bonding structure represented by formula (2) may be 80:20 to 99:1. In some embodiments, in the butadiene block, the molar ratio of the 1,2-bonding structure represented by formula (1) to the 1,4-bonding structure represented by formula (2) may be 5:1 to 7:1. In the present disclosure, the molar ratio of formula (1) and formula (2) is determined by a proton nuclear magnetic resonance (¹H-NMR) method.

The second styrene-based copolymer may be a styrene block copolymer or a styrene random copolymer. In some embodiments, the second styrene-based copolymer is a styrene block copolymer which has less than 50 wt % of randomized comonomer repeat units based on the total weight of the second styrene block copolymer being 100 wt %. In some embodiments, the second styrene-based copolymer may be a styrene block copolymer selected from a group consisting of a styrene-butadiene block copolymer (SB), a styrene-butadiene-styrene tri-block copolymer (SBS), a butadiene-styrene-butadiene tri-block copolymer (BSB), and any combinations thereof, but the present disclosure is not limited thereto. In some embodiments, the second styrene-based copolymer may be a styrene-butadiene-styrene tri-block copolymer (SBS) having a weight average molecular weight that is lower than 80,000 g/mol. In some embodiments, the second styrene-based copolymer may be a styrene-butadiene-styrene tri-block copolymer (SBS) that is solid at 25° C.

In some embodiments, the second styrene-based copolymer may have a viscosity within a range of higher than or equal to 54.4 Pa·s and lower than 521.4 Pa·s. In some embodiments, the second styrene-based copolymer may has a viscosity within a range of 114.8 Pa·s to 327.4 Pa·s, providing superior mechanical performance. The viscosity is determined by a rheometer, following the method outlined below: preparing a sample with a concentration of 35 wt % in methyl ethyl ketone (MEK), and setting a parameter of shear rate to 50 s⁻¹ at a temperature of 25° C.

In some embodiments, the second styrene-based copolymer may be produced using a method that is substantially similar to the method for producing the first styrene-based copolymer, and will therefore not be repeated here.

The second styrene-based copolymer has high molecular entanglements. The second styrene-based copolymer may have desired thermal and physical properties. Therefore, thermal and physical properties of a polymer composite including the same can be improved.

The polymer composite of the present disclosure including the first styrene-based copolymer and the second styrene-based copolymer above may be incorporated with a hydrocarbon resin to provide a low dielectric resin composition having a low dielectric loss tangent (Df). In some embodiments, the weight ratio of the first styrene-based copolymer to the second styrene-based copolymer may be within a range of 5/95 to 95/5, of 10/90 to 90/10, of 20/80 to 80/20, or of 25/75 to 80/20. In some embodiments, the weight ratio of the first styrene-based copolymer to the second styrene-based copolymer may be 5/95, 10/90, 15/85, 20/80, 25/75, 30/70, 35/65, 40/60, 45/55, 50/50, 55/45, 60/40, 65/35, 70/30, 75/25, 80/20, 85/15, 90/10, or 95/5, but the present disclosure is not limited thereto. In some embodiments, the polymer composite of the present disclosure can also improve thermal properties and/or mechanical properties of a low dielectric resin composition including a hydrocarbon resin, while preventing embrittlement during the use of the hydrocarbon resin. Therefore, in some embodiments, the low dielectric resin composition including the polymer composite of the present disclosure and the hydrocarbon resin may include good thermal properties and/or mechanical properties (high peel strength).

The polymer composite of the present disclosure may be used to manufacture a metal foil laminated board having dielectric loss tangent (Df) that is less than or equal to 0.00200. In particular, the polymer composite of the present disclosure may be incorporated with a hydrocarbon resin to provide a low dielectric resin composition having a low dielectric loss tangent (Df) which can be used to manufacture a metal foil laminated board. In some embodiments, the metal foil laminated board comprises a glass fiber cloth having a dielectric loss tangent (Df) that is less than or equal to 0.0030.

An embodiment of the disclosure provides a low dielectric resin composition. In some embodiments, the low dielectric resin composition may comprise the aforementioned polymer composites and a poly (arylene ether) compound. In some embodiments, the low dielectric resin composition is free of a poly (arylene ether) compound. In the present disclosure, the poly (arylene ether) compound may be a polymer includes a plurality of units represented by formula (3) below:

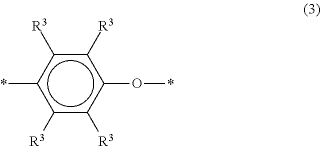

wherein for each structural unit, each R³ is independently hydrogen or C₁₋₄ alkyl group, and “*” represents a connecting site that connects other groups.

The low dielectric resin composition of the present disclosure includes a hydrocarbon resin, a first styrene-based copolymer and a second styrene-based copolymer. In some embodiments, the first styrene-based copolymer has a weight average molecular weight that is lower than 20,000 g/mol and the second styrene-based copolymer has a weight average molecular weight that is higher than 20,000 g/mol, but the present disclosure is not limited thereto. In some embodiments, the first styrene-based copolymer is liquid at 25° C., and the second styrene-based copolymer is solid at 25° C. In some embodiments, the hydrocarbon resin, the first styrene-based copolymer and the second styrene-based copolymer can be separated from each other by common purification methods.

In some embodiments, based on the total weight of the low dielectric resin composition, the low dielectric resin composition include more than 53 wt % of the hydrocarbon resin. In some embodiments, based on the total weight of the low dielectric resin composition, the low dielectric resin composition include more than 57 wt % of the hydrocarbon resin. In some embodiments, based on the total weight of the low dielectric resin composition, the low dielectric resin composition includes more than 54 wt %, 55 wt %, 56 wt %, 57 wt %, 58 wt %, 59 wt %, 60 wt %, 61 wt % or 62 wt % of the hydrocarbon resin.

In some embodiments, based on 100 parts by weight of the hydrocarbon resin, the low dielectric resin composition may include 1 to 50 parts by weight of the first styrene-based copolymer and 1 to 50 parts by weight of the second styrene-based copolymer. In some embodiments, based on 100 parts by weight of the hydrocarbon resin, the low dielectric resin composition may include 1 part to less than 50 parts by weight of the first styrene-based copolymer and 1 to less than 50 parts by weight of the second styrene-based copolymer. In some embodiments, based on 100 parts by weight of the hydrocarbon resin, the low dielectric resin composition may include 4 to 40 parts by weight of the first styrene-based copolymer and 2 to 20 parts by weight of the second styrene-based copolymer. In some embodiments, based on 100 parts by weight of the hydrocarbon resin, the low dielectric resin composition may include 4 to 20 parts by weight of the first styrene-based copolymer and 2 to 17 parts by weight of the second styrene-based copolymer.

The weight ratio of the hydrocarbon resin to the sum of the first styrene-based copolymer and the second styrene-based copolymer is in a range of greater than 100/50 and less than or equal to 100/10. The weight ratio of the hydrocarbon resin to the sum of the first styrene-based copolymer and the second styrene-based copolymer is in a range of greater than 100/35 and less than or equal to 100/10. In the embodiments where the weight ratio of the hydrocarbon resin to the sum of the first styrene-based copolymer and the second styrene-based copolymer is in a range above, the low dielectric resin composition shows mechanical strength (peel strength). In some embodiments, the weight ratio of the hydrocarbon resin to the sum of the first styrene-based copolymer and the second styrene-based copolymer may be from 100/45 to 100/10, 100/40 to 100/15, 100/35 to 100/20, or 100/34 to 100/20. In some embodiments, the weight ratio of the hydrocarbon resin to the sum of the first styrene-based copolymer and the second styrene-based copolymer may be 100/21.

The weight ratio of the first styrene-based copolymer to the second styrene-based copolymer may be within a range of 5/95 to 95/5, from 10/90 to 90/10, from 20/80 to 80/20, or from 25/75 to 80/20. In some embodiments, the weight ratio of the first styrene-based copolymer to the second styrene-based copolymer may be 5/95, 10/90, 15/85, 20/80, 25/75, 30/70, 35/65, 40/60, 45/55, 50/50, 55/45, 60/40, 65/35, 70/30, 75/25, 80/20, 85/15, 90/10, or 95/5, but the present disclosure is not limited thereto.

The first styrene-based copolymer and the second styrene-based copolymer included in the low dielectric resin composition are substantially similar to the first styrene-based copolymer and the second styrene-based copolymer included in the polymer composite above, and will therefore not be repeated here.

The hydrocarbon resin included in the low dielectric resin composition may include repeating units (A) derived from a bridged ring monomer compound, repeating units (B) derived from a mono vinyl aromatic compound, and repeating units (C) derived from divinyl aromatic compounds. In some embodiments, based on 100 mol % of the total units in the hydrocarbon resin, the hydrocarbon resin may include: 0-40 mol % of repeating units (A) derived from a bridged ring monomer compound; 15-92 mol % of repeating units (B) derived from a mono vinyl aromatic compound; and 8-80 mol % of repeating units (C) derived from a divinyl aromatic compound.

The term “bridged ring monomer compounds” used herein refers to compounds that have bridged ring structures and can be polymerized with the same compounds or different compounds to form polymers. The bridged ring structure refers to a structure having at least two carbocycles, and the at least two carbocycles share two carbon atoms that are not directly connected. In some embodiments, the bridged ring structure in the bridged ring monomer compound may include 3-12 ring atoms and 1-2 double bonds. In some embodiments, the bridged ring structure can be unsubstituted. In some embodiments, at least one hydrogen atom on the bridged ring structure can be substituted by at least one substituent selected from a group consisting of a C₁₋₂₀ alkyl group, a C₂₋₂₀ alkenyl group, and a carboxylate group having C₁₋₂₀ alkyl chain group. In some embodiments, the bridged ring structure may have at least two substituents. The at least two substituents may be any two substituents selected from a group consisting of a C₁₋₂₀ alkyl group, a C₂₋₂₀ alkenyl group, and a carboxylate group having C₁₋₂₀ alkyl chain group. Adjacent substituents among the at least two substituents may together form a ring. Examples of the bridged ring monomer compounds include, but are not limited to, a norbornene (NB), a dicyclopentadiene (DCPD), a dicycloheptadiene (NBD), a 5-acetyl-2-norbornene, a methyl 5-norbornene-2-carboxylate, a vinyl norbornene, an ethylidene-norbornene, or a combination thereof.

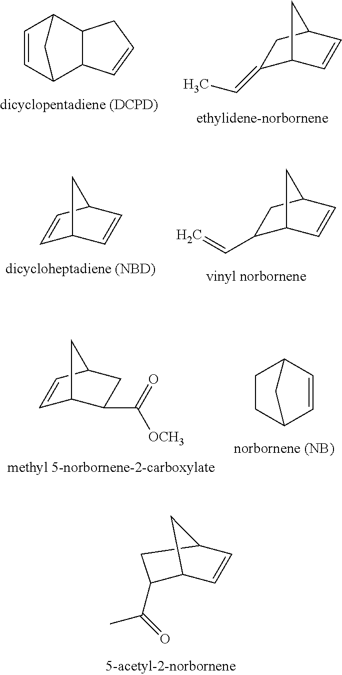

The repeating unit (A) derived from a bridged ring monomer compound includes the bridged ring structure from the bridged ring monomer compound. Therefore, the repeating unit (A) may include a bridged ring structure including 3-12 ring atoms and 0-1 double bonds. In some embodiments, the repeating unit (A) may have the following structure, but the disclosure is not limited thereto:

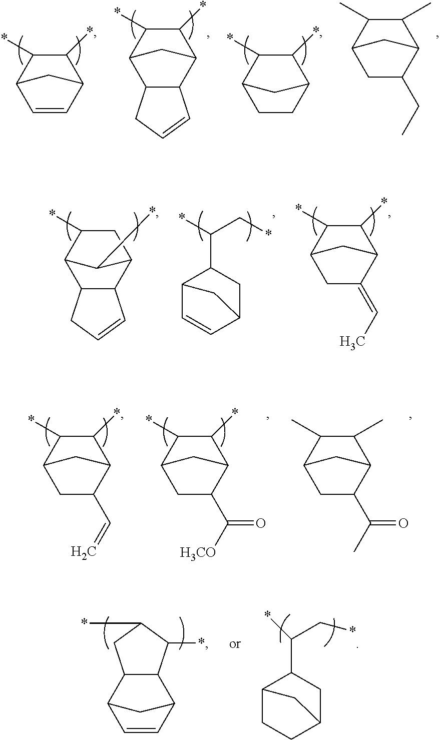

In the above structures, “*” represents a connecting site that connects other groups. Compared with linear repeating units, the repeating units (A) with bridged ring structures have higher rigidity. Therefore, it can increase the glass transition temperature of the hydrocarbon resin or improve the thermal performance of the hydrocarbon resin. When the content of the repeating units (A) in the hydrocarbon resin is too high, for example, above 40 mol %, the cost-effectiveness of the hydrocarbon resin will be reduced. In some embodiments, the hydrocarbon resin of the present disclosure may include 0-38 mol %, 0-30 mol %, 0-25 mol %, 0-20 mol %, 20-40 mol %, 20-38 mol %, 20-30 mol %, or 20-25 mol % of the repeating units (A). In some embodiments, the hydrocarbon resin of the disclosure may include 3 mol %, 5 mol %, 7 mol %, 9 mol %, 10 mol %, 20 mol %, 22 mol %, 25 mol %, 30 mol %, 32 mol %, 35 mol %, or 38 mol % of the repeating units (A).

The term “monovinyl aromatic compound” used herein refers to a compound including a carbocyclic aromatic structure, and one hydrogen on a ring carbon atom of the carbocyclic aromatic structure is substituted by a vinyl group. In some embodiments, the vinyl group may be unsubstituted. In some embodiments, at least one hydrogen atom on the vinyl group may be substituted by a C₁₋₂₀ alkyl group. In some embodiments, the carbocyclic aromatic structure may include 6-60 or 6-20 ring carbon atoms. In some embodiments, the carbocyclic aromatic structure may be unsubstituted. In some embodiments, at least one hydrogen on the ring carbon atom in the carbocyclic aromatic structure may be substituted by a C₁₋₂₀ alkyl group. Examples of the monovinyl aromatic compound include, but are not limited to, a styrene, a methylstyrene, an ethylstyrene (EVB), or any combination thereof.

The repeating unit (B) derived from a monovinyl aromatic compound includes the carbocyclic aromatic structure from the monovinyl aromatic compound. For example, in some embodiments, the repeating unit (B) may have the following structure, but the disclosure is not limited thereto:

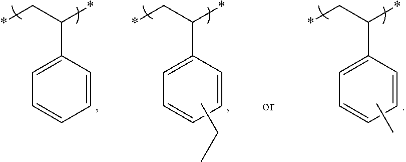

In the above structures, “*” represents a connecting site that connects other groups.

The repeating unit (B) can increase the solubility of the hydrocarbon resin in solvents such as toluene. When the content of the repeating units (B) in the hydrocarbon resin is too low, for example, less than 15 mol %, the solubility of the hydrocarbon resin in the solvent is poor. When the content of the repeating units (B) in the hydrocarbon resin is too high, for example, higher than 92 mol %, other properties of the hydrocarbon resin, such as its thermal properties, may deteriorate. In some embodiments, the hydrocarbon resin of the disclosure may include 15-92 mol % of repeating units (B). In some embodiments, the hydrocarbon resin polymer of the disclosure may include 20-92 mol %, 20-90 mol %, 25-85 mol %, 30-80 mol %, 35-80 mol %, 40-80 mol %, or 45-80 mol % of repeating units (B). In some embodiments, the hydrocarbon resin polymer of the disclosure may include 46 mol %, 48 mol %, 50 mol %, 55 mol %, 60 mol %, 67 mol %, 72 mol %, 76 mol %, or 78mol % of repeating units (B).

The term “divinyl aromatic compound” used herein refers to a compound including a carbocyclic aromatic structure, and two hydrogen on a ring carbon atom or ring carbon atoms of the carbocyclic aromatic structure are substituted by vinyl groups. In some embodiments, the vinyl groups may be unsubstituted. In some embodiments, at least one hydrogen atom on the vinyl groups may be substituted by a C₁₋₂₀ alkyl group. In some embodiments, the carbocyclic aromatic structure may include 6-60 or 6-20 ring carbon atoms. In some embodiments, the carbocyclic aromatic structure may be unsubstituted. In some embodiments, at least one hydrogen on the ring carbon atom in the carbocyclic aromatic structure may be substituted by a C₁₋₂₀ alkyl group. Examples of the divinyl aromatic compound include, but it is not limited thereto, divinylbenzene (DVB), diisopropenylbenzene, or any combination thereof.

The repeating unit (C) derived from a divinyl aromatic compound includes the carbocyclic aromatic structure from the divinyl aromatic compound. In some embodiments, the repeating units (C) may include crosslinking units and non-crosslinking units. In some embodiments, the repeating units (C) may include crosslinking units represented as follows:

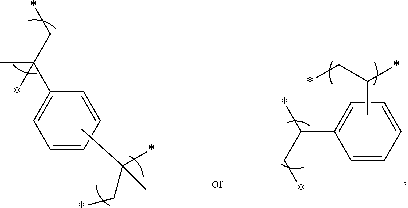

but the disclosure is not limited thereto. In some embodiments, the repeating units (C) may include non-crosslinking units represented as follows, but the disclosure is not limited thereto:

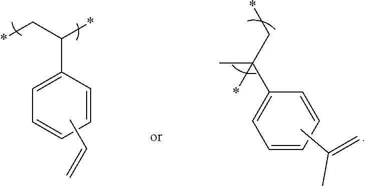

In the above structures, “*” represents a connecting site that connects other groups.

A cross-linking degree of the repeat units (C) is determined using 13C-NMR (Nuclear Magnetic Resonance, NMR) and 1-H-NMR, with the sample prepared in CDCl₃; and, the cross-linking degree is then calculated by the following formula:

$$\frac{the crosslinking units of the repeating units ( C )}{\begin{matrix}the crosslinking units of the repeating units ( C ) + \\ the non - crosslinking units of the repeating units ( C )\end{matrix}}$$

In some embodiments, the cross-linking degree of the repeating units (C) is 0.2-0.6. The range of cross-linking degree contributes to superior thermal and electrical properties without inducing the processability problem. The higher cross-linking degree of the hydrocarbon resin has, the better the thermal performance, thermal stability, and/or the electrical performance of the hydrocarbon resin composition, but its processability will be deteriorated when the cross-linking degree is higher than 0.6. In some embodiments, the cross-linking degree of the repeating units (C) may be 0.2-0.5. In some embodiments, the cross-linking degree of the repeating units (C) may be 0.3, 0.35, 0.4, or 0.45, but the present disclosure is not limited thereto.

The repeating units (C) can increase the cross-linking degree of the hydrocarbon resin. The higher cross-linking degree of the hydrocarbon resin has, the better the thermal performance, thermal stability, and/or the electrical performance of the hydrocarbon resin. When the content of the repeating units (C) in the hydrocarbon resin is too low, for example, less than 8 mol %, the cross-linking degree of the hydrocarbon resin is low, and the thermal and/or electrical performance of the hydrocarbon resin are poor. When the content of the repeating units (C) in the hydrocarbon resin is too high, for example, higher than 80 mol %, the processability of the hydrocarbon resin will be deteriorated. In some embodiments, the hydrocarbon resin of the disclosure may include 8-80 mol %, 8-70 mol %, 8-60 mol %, 8-50 mol %, 8-45 mol %, 8-40 mol %, or 8-35 mol % of repeating units (C). In some embodiments, the hydrocarbon resin of the disclosure may include 8 mol %, 9 mol %, 10 mol %, 11 mol %, 12 mol %, 16 mol %, 20 mol %, 30 mol %, 32 mol %, 35 mol %, 40 mol %, or 45 mol % of repeating units (C). In some embodiments, the sum of the repeating units (A) and the repeating units (C) is greater than or equal to 8 mol %. In some embodiments, the sum of the repeating units (A) and the repeating units (C) is greater than or equal to 13 mol % or even greater than or equal to 15 mol %. As mentioned above, both the repeating units (A) and the repeating units (C) will affect the thermal properties and thermal stability of the hydrocarbon resin. The inventors found that when the sum of the repeating units (A) and the repeating units (C) is greater than or equal to 8 mol %, a hydrocarbon resin has excellent thermal properties and thermal stability can be provided.

In some embodiments, reactive double bonds may be included in the hydrocarbon resin. The term “reactive double bond” used herein refers to the double bonds in the repeating units (A) or the repeating units (C) that can react with other compounds or polymers. For example, in some embodiments, the reactive double bonds include the double bonds in repeating units (A) represented as follows:

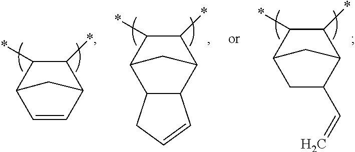

and the double bond not in the benzene ring and in repeating units (C) represented as follows:

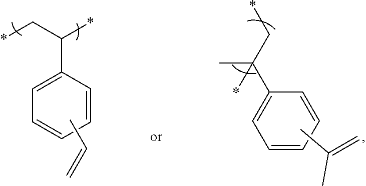

but the disclosure is not limited thereto.

In some embodiments, a content of hydrogen atoms in the reactive double bonds in the hydrocarbon resin is less than 10%. When the hydrogen atom content in the reactive double bonds in the hydrocarbon resin is too high, such as higher than 10%, the hydrocarbon resin is susceptible to oxidation during the heating process, resulting in the hydrocarbon resin having poor electrical properties. In some embodiments, the hydrogen atom content in the reactive double bonds in the hydrocarbon resin is greater than 2.2%. In some embodiments, the hydrogen atom content in the reactive double bonds in the hydrocarbon resin is in the range of greater than 2.2% and less than 10%. In some embodiments, the hydrogen atom content in the reactive double bonds in the hydrocarbon resin is in the range of greater than or equal to 2.3% and less than 6.6%. When the hydrogen atom content in the reactive double bonds in the hydrocarbon resin is too low, for example, less than 2.2%, a peel strength of a layer including the hydrocarbon resin is too small. In some embodiments, the hydrogen atom content in the reactive double bonds in the hydrocarbon resin may be 2.3%-10%, 2.3%-10%, 2.3%-9%, 2.3%-7%, 2.3%-6%, or 2.3-4%. When the hydrogen atom content in the reactive double bonds in the hydrocarbon resin is within the above range, the hydrocarbon resin is not susceptible to oxidation, and it tends to complete a crosslinking reaction before being oxidized in a high-temperature environment (for example, above 150° C.). Therefore, the electrical performance of the hydrocarbon resin can be improved. In some embodiments, a number average molecular weight (Mn) of the hydrocarbon resin may be 2,500-13,000 g/mol, determined by gel permeation chromatography (GPC). When the number average molecular weight of the hydrocarbon resin is too high, the solubility of the hydrocarbon resin would be decreased.

The hydrocarbon resin of the disclosure having the above features has good thermal performance, thermal stability, and/or good electrical performance. For example, in some embodiments, the hydrocarbon resin of the disclosure has a glass transition temperature greater than about 100° C., a dielectric constant (Dk) less than about 3.4, a dielectric loss tangent (Df) less than about 0.0030, a difference of the dielectric constants and/or a difference of the dielectric loss tangents before and after the heating process are small, and/or the dielectric loss tangent is less than about 0.0020 after the heating process. The Dk/Df of hydrocarbon resin is analyzed by following method, comprising: dissolving 20 g resin in 20 g toluene to form a mixture; immersing a glass fiber cloths into the mixture for 16 hours to form samples; and measuring the Dk/Df of the samples at 28 GHz by a network analyzer software (network analyzer Keysight, P5007A, SCR). The glass transition temperature of the hydrocarbon resin is measured by dynamic mechanical analysis (DMA, TA/Q800). In addition, the hydrocarbon resin of the disclosure also has good solubility and/or processability. Therefore, the hydrocarbon resin of the disclosure can be easily dissolved in a solvent to form a resin composition having good thermal performance, thermal stability, good electrical performance, and/or good processability.

In some embodiments, the low dielectric resin composition may further include an additive to modify performance of the low dielectric resin composition. In some embodiments, based on 100 parts by weight of the sum of the hydrocarbon resin, the first styrene-based copolymer, and the second styrene-based copolymer, the low dielectric resin composition may include 1 to 50 parts by weight of the additive. The additive may be selected from a group consisting of an initiator, a flame retardant, an inorganic filler, a crosslinking aid, and any combinations thereof. In the present disclosure, the initiator, the flame retardant, the inorganic filler, and the crosslinking aid are not particularly limited.

Examples of the initiator include benzoyl peroxide, cumene hydroperoxide, 2,5-dimethylhexane-2,5-dihydroperoxide, 2,5-dimethyl-2,5-di (t-butylperoxy) hexine-3, di-t-butyl peroxide, t-butylcumyl peroxide, α,α′-bis (t-butylperoxy-m-isopropyl)benzene, 2,5-dimethyl-2,5-di (t-butylperoxy) hexane, dicumyl peroxide, di-t-butyl peroxyisophthalate, t-butyl peroxybenzoate, 2,2-bis (t-butylperoxy) butane, 2,2-bis (t-butylperoxy) octane, 2,5-dimethyl-2,5-di (benzoylperoxy) hexane, di (trimethylsilyl) peroxide, trimethylsilyl triphenylsilyl peroxide, or any combinations thereof, but the present disclosure is not limited thereto. In some embodiments, the initiator is a peroxide-type compound. In some embodiments, based on 100 parts by weight of the sum of the hydrocarbon resin, the first styrene-based copolymer, and the second styrene-based copolymer, the low dielectric resin composition may include 1 to 10 parts by weight of the initiator, but the present disclosure is not limited thereto.

Examples of the flame retardant include a halogen-based flame retardant (such as a bromine-based flame retardant), a phosphorus-based flame retardant, other suitable retardants, or any combinations thereof, but the present disclosure is not limited thereto. Examples of the phosphorus-containing flame retardant include a phosphoric acid ester (such as a condensed phosphoric acid ester and a cyclic phosphoric acid ester), a phosphazene compound (such as a cyclic phosphazene compound), a phosphinate-based flame retardant (such as aluminum dialkyl phosphinate), a melamine-based flame retardant (such as melamine phosphate and melamine polyphosphate), other suitable retardants, or any combinations thereof, but the present disclosure is not limited thereto. In some embodiments, based on 100 parts by weight of the sum of the hydrocarbon resin, the first styrene-based copolymer, and the second styrene-based copolymer, the low dielectric resin composition may include 1 to 20 parts by weight of the phosphorus-containing flame retardant, but the present disclosure is not limited thereto.

In some embodiments of the present disclosure, examples of the inorganic filler may include silica, alumina, talc, aluminum hydroxide, magnesium hydroxide, titanium oxide, mica, aluminum borate, barium sulfate, calcium carbonate, other suitable materials, or any combinations thereof, but the present disclosure is not limited thereto. In some embodiments, the inorganic filler is silica. In some embodiments, based on 100 parts by weight of the sum of the hydrocarbon resin, the first styrene-based copolymer, and the second styrene-based copolymer, the low dielectric resin composition may include 10 to 50 parts by weight of the inorganic filler, but the present disclosure is not limited thereto.

The crosslinking aid may enhance a thermal property of the low dielectric resin composition. Examples of the crosslinking aid include triallyl cyanurate (TAC), triallyl isocyanurate (TAIC), trimethallyl isocyanurate (TMAIC), diallyl phthalate, divinylbenzene, 1,2,4-triallyl trimellitate, or any combinations thereof, but the present disclosure is not limited thereto. In some embodiments, the low dielectric resin composition includes the crosslinking aid and the initiator, wherein the initiator is a peroxide-type compound. In some embodiments, the crosslinking aid is divinylbenzene, triallyl isocyanurate (TAIC), or a combination thereof, but the present disclosure is not limited thereto. In some embodiments, the crosslinking aid is divinylbenzene. In some embodiments, based on 100 parts by weight of the sum of the hydrocarbon resin, the first styrene-based copolymer, and the second styrene-based copolymer, the low dielectric resin composition may include 1 to 50 parts by weight of the crosslinking agent, but the present disclosure is not limited thereto.

A method for producing the low dielectric resin composition in the present disclosure is not particularly limited. In some embodiments, the low dielectric resin composition is prepared by mixing the hydrocarbon resin, the first styrene-based copolymer, the second styrene-based copolymer, and optional additives with an organic solvent in a batch. In some embodiments, the organic solvent may include methyl ethyl ketone, toluene, or a combination thereof, but the present disclosure is not limited thereto.

The mixing process may be performed simultaneously or sequentially, but the present disclosure is not limited thereto. In some embodiments, the mixing process is conducted with a suitable mixer selected according to the amount of low dielectric resin composition to be prepared, but the present disclosure is not limited thereto. In some embodiments, the mixing process is conducted at room temperature and is completed until the hydrocarbon resin, the first styrene-based copolymer, the second styrene-based copolymer, and the optional additives are completely dispersed.

The low dielectric resin composition of the present disclosure has a dielectric loss tangent (Df) that is less than or equal to 0.00200. The low dielectric resin composition of the present disclosure may be used to manufacture a metal foil laminated board having dielectric loss tangent (Df) that is less than or equal to 0.00200.

An embodiment of the disclosure provides a prepreg manufactured from a low dielectric resin composition above. That is, an embodiment of the disclosure provides a prepreg manufactured from a low dielectric resin composition including a hydrocarbon resin and a polymer composite including a first styrene-based copolymer and a second styrene-based copolymer above. In some embodiments, the weight ratio of the first styrene-based copolymer to the second styrene-based copolymer is from 5/95 to 95/5. In some embodiments, the first styrene-based copolymer has a weight average molecular weight that is lower than 20,000 g/mol and the second styrene-based copolymer has a weight average molecular weight that is higher than 20,000 g/mol, but the present disclosure is not limited thereto. In some embodiments, the first styrene-based copolymer is liquid at 25° C., and the second styrene-based copolymer is solid at 25° C.

A method for preparing the prepreg is not particularly limited. In some embodiments, the prepreg is prepared from a mixture of a fibrous base material and the low dielectric resin composition above or a resin varnish containing the low dielectric resin composition above. In some embodiments, the prepreg is prepared by a prepreg preparation method. The prepreg preparation method includes: providing a resin varnish containing the low dielectric resin composition above; forming a mixture by dipping a fibrous base material into the resin varnish; and heating the mixture to 100 to 180° C. to remove the solvent and to obtain the prepreg in a semi-cured state.

In some embodiments, the resin varnish is prepared by a resin varnish preparation method. The resin varnish preparation method includes a dissolving step and a dispersing step. In some embodiments, the dissolving step includes dissolving the hydrocarbon resin, the first styrene-based copolymer, the second styrene-based copolymer, and optional additives which can be soluble in an organic solvent until they are completely dispersed. In some embodiments, the dispersing step includes adding and dispersing the optional additives which cannot be soluble in the organic solvent (such as the inorganic filler) using a ball mill, a bead mill, a planetary mixer, a roll mill, other suitable device, or any combination thereof until a predetermined dispersion state is achieved.

Examples of the fibrous base material include a glass fiber cloth, an aramid cloth, a polyester cloth, a glass nonwoven fabric, an aramid nonwoven fabric, a polyester nonwoven fabric, a pulp paper, a printer paper, other suitable materials, or any combinations thereof, but the disclosure is not limited thereto. In some embodiments, the fibrous base material is a glass fiber cloth having a dielectric loss tangent (Df) that is less than or equal to 0.0030.

The prepreg of the present disclosure has a dielectric loss tangent (Df) that is less than or equal to 0.00200 may be used to prepared a metal foil laminated board having dielectric loss tangent (Df) that is less than or equal to 0.00200.

An embodiment of the disclosure provides a metal foil laminated board including the prepreg above. In some embodiments, a metal foil laminated board having a dielectric loss tangent (Df) that is less than or equal to 0.00200 is manufactured by using the aforementioned polymer composite to form a mixture including hydrocarbon resin. In some embodiments, the metal foil laminated board has a structure that a metal foil is stacked on both the top of the prepreg or the prepreg stack, and the stacked structure is integrally laminated by hot press molding to obtain a double-sided metal-clad or single-sided metal-clad laminate plate. In some embodiments, the hot press conditions for total curing may be appropriately set according to the thickness of the metal foil laminated board to be produced, the kind of hydrocarbon resin composition for the prepreg, and the like. For example, the hot press conditions may be set such that the temperature is 170 to 220° C., the pressure is 1.0 to 4.0 MPa, and the time is 60 to 180 minutes.

FIGURE is a schematic diagram of a metal foil laminated board 10 according to an embodiment of the disclosure. As shown in FIGURE, the metal foil laminated board 10 includes a base 101, a polymer layer 103 disposed on the base 101, and an adhesive layer 105 disposed between the base 101 and the polymer layer 103. The adhesive layer 105 connects the substrate 101 and the polymer layer 103. The polymer layer 103 may include the prepreg mentioned above. The metal foil laminated board including the prepreg mentioned above may have a dielectric loss tangent (Df) that is less than or equal to 0.00200. In some embodiments, metal foil laminated board including the prepreg mentioned above may have excellent thermal properties, thermal stability, mechanical properties (high peel strength) and/or reliability.

In some embodiments, the base 101 may include a metal layer. In some embodiments, the base 101 may include a copper foil. In some embodiments, the adhesive layer 105 may include any material that can connect the substrate 101 and the polymer layer 103. In some embodiments, the adhesive layer 105 may include a silane adhesive.

One or more embodiments of the disclosure will be described in detail with reference to the following examples. However, these examples are only used to illustrate the embodiments of the disclosure and are not intended to limit the scope of the embodiments of the disclosure.

### [Preparation of Hydrocarbon Resins HC 1-5]

Bridged ring monomer compounds, monovinyl aromatic compounds, and divinyl aromatic compounds and toluene were added to a two-necked flask to form a mixture in ratios shown in Table 1 below. Catalysts shown in Table 1 were added to the mixtures. The mixtures were stirred for 3 hours at reaction temperatures shown in Table 1 below to polymerize the bridged ring monomer compounds, monovinyl aromatic compounds, and divinyl aromatic compounds. Ammonium hydroxide (NH₄OH) was added to the two-necked flask to terminate the polymerization reaction. A polymer solution obtained from the polymerization reaction was dropped into isopropanol to obtain a white solid. The white solid was filtered and dried under vacuum to obtain the hydrocarbon resins HC 1-5.

### [Measurement of Hydrogen Atom Content in Reactive Double Bond]

The hydrocarbon resins HC 1-5 were dissolved in a deuterated chloroform (CDCl₃). The hydrogen atom contents in reactive double bonds of the hydrocarbon resins HC 1-5 were respectively measured by NMR (JEOL, JNM-ECZ400S/L1). Specifically, the hydrogen atom contents in reactive double bonds were calculated by dividing the sum of the integral values of the number of hydrogen atoms in the reactive double bonds by the sum of the integral values of all hydrogen atoms in the hydrocarbon resins HC 1-5.

### [Measurement of Number Average Molecular Weight (Mn) and Polymer Dispersity Index (PDI)]

Polystyrene was used as a standard to measure number average molecular weights and polymer dispersity indexes (PDI) of the hydrocarbon resins HC 1-5 by a gel permeation chromatography (GPC) (Waters APC, column: Waters Acquity XT 900).

5 mL of tetrahydrofuran (THF) was added to 0.01 g of the hydrocarbon resins HC 1-5 respectively, to obtain samples of the hydrocarbon resins HC 1-5. The samples of the hydrocarbon resins HC 1-5 were analyzed by an instrument after filtered by a 0.22 μm filter to obtain the number average molecular weight (Mn) and polymer dispersity index (PDI) of the hydrocarbon resins HC 1-5. The results of the measured properties of the hydrocarbon resins HC 1-5 are shown in Table 1 below.

TABLE 1

| Hydrocarbon resin | HC 1 | HC 2 | HC 3 | HC 4 | HC 5 |
|---|---|---|---|---|---|
| Norbornene (mol %) | — | — | — | — | 38 |
| DCPD(mol %) | — | 20 | 22 | 20 | — |
| Styrene (mol %) | 87 | 48 | 70 | 65 | 36 |
| EVB (mol %) | 4.81 | — | 6 | 5.6 | 9.6 |
| DVB(mol %) | 8.19 | — | 10.2 | 9.5 | 16.4 |
| 1,3- | — | 32 | — | — | — |
| Diisopropenylbenzene | | | | | |
| (mol %) | | | | | |
| Catalyst | BF₃•OEt | TiCp₂Cl₂/ | BF₃•OEt₂ | BF₃•OEt | BF₃•OEt₂ |
| | | BF₃•OEt₂ | | | |
| Reaction temperature | 0 | 0 | 15 | 0 | 60 |
| (° C.) | | | | | |
| Yield (%) | 42.9 | 48.4 | 40.1 | 44.4 | 58.9 |
| Mn (g/mol) | 12762 | 5781 | 6630 | 5708 | 3337 |
| PDI | 9.17 | 21.1 | 8.89 | 2.69 | 3.58 |
| hydrogen atom | 2.3 | 5.5 | 2.9 | 3.3 | 6.6 |
| content (%) | | | | | |

* mol % indicates mole fraction.

### Preparation of Examples E1-E13 and Comparative Examples C1 and C2

### Materials

### Hydrocarbon Resin: Hydrocarbon Resins HC 1-5 Above.

### First Styrene-Based Copolymer

Ricon-100: a styrene-butadiene random copolymer (SBR) manufactured by Cray Valley. Ricon-100 has a number average molecular weight of 4,500 Da, a viscosity @ 45° C. of 40,000 cps, the styrene content of 17-27 wt %, the 1,2-vinyl content of 70 wt %, a Tg of −22° C., and a specific gravity@ 25° C. of 0.92 g/cm³.

SBS-L: a styrene-butadiene-styrene tri-block copolymer (SBS) having a weight average molecular weight of 6,000 Da and PDI of 1.04. SBS-L has the molar ratio of the 1,2-bonding structure to the 1,4-bonding structure in the butadiene block is 5:1 to 7:1, and the weight ratio of the styrene block to the butadiene block is 10:90 to 50:50.

### Second Styrene-Based Copolymer

SBS-1: a styrene-butadiene-styrene tri-block copolymer (SBS) having a weight average molecular weight of 80,000 Da and a viscosity of 521.4 Pa·s. SBS-1 has the molar ratio of the 1,2-bonding structure to the 1,4-bonding structure in the butadiene block is 5:1 to 7:1, and the weight ratio of the styrene block to the butadiene block is 50:50.

SBS-2: a styrene-butadiene-styrene tri-block copolymer (SBS) having a weight average molecular weight of 40,000 Da and a viscosity of 114.8 Pa·s. SBS-2 has the molar ratio of the 1,2-bonding structure to the 1,4-bonding structure in the butadiene block is 5:1 to 7:1, and the weight ratio of the styrene block to the butadiene block is 50:50.

Crosslinking aid: a divinylbenzene compound manufactured by Deltech, trade name “DVB”.

Initiator: a α,α-Bis (t-butylperoxy) diisopropylbenzene compound manufactured by NOF, trade name “PERBUTYL P”.

Additives-inorganic filler: a silica filler manufactured by Admatch, trade name “SS-10”.

### Preparation and Measure Dk/Df of Metal Foil Laminated Boards of Examples E1-E11 and Comparative Examples C1 and C2

The materials above were mixed with 50 to 60 parts by weight of toluene in ratios shown in Tables 2-7 below to form resin varnishes of Examples E1-E13 and Comparative Examples C1 and C2. The abbreviation phr means “parts per hundred parts of resin”. Two pieces of glass fiber cloth (Asahi 2116, Dk/Df=3.3/0.0030@10 GHz) were immersed in the resin varnishes of Examples E1-E13 and Comparative Examples C1 and C2 respectively, and baked at 160-170° C. for 5-15 minutes to form two polymer layers of Examples E1-E13 and Comparative Examples C1 and C2. A high temperature elongation copper foil was then placed between the two polymer layers of Examples E1-E13 and Comparative Examples C1 and C2 respectively. The high temperature elongation copper foil and the two polymer layers of Examples E1-E13 and Comparative Examples C1 and C2 were laminated under a pressure of 400 psi and a temperature of 210° C. for 1 hour to obtain metal foil laminated boards of Examples E1-E13 and Comparative Examples C1 and C2 respectively.

Measure the Dk/Df of the metal foil laminated boards of Examples E1-E13 and Comparative Examples C1 and C2 at 10 GHz by a network analyzer software (network analyzer Keysight, P5007A, SCR), results are shown in Tables 2-7 below.

TABLE 2

| Examples | | | E1 | E2 | E3 |
|---|---|---|---|---|---|
| Hydrocarbon | HC 1(phr) | | 0 | 100 | 0 |
| resin (H) | HC 2(phr) | | 0 | 0 | 100 |
| | HC 4(phr) | | 100 | 0 | 0 |
| styrene- | First | Ricon100(phr) | 14.7 | 0 | 0 |
| based | styrene- | SBS-L(phr) | 0 | 14.7 | 14.7 |
| polymer (S) | based | | | | |
| | copolymer | | | | |
| | Second | SBS-2(phr) | 6.3 | 6.3 | 6.3 |
| | styrene- | | | | |
| | based | | | | |
| | copolymer | | | | |

| | | | |
|---|---|---|---|
| Ratio of H/S | 100/21 | 100/21 | 100/21 |
| crosslinking aid (DVB) (phr) | 9 | 9 | 9 |
| Initiator (PERBUTYL P) (phr) | 1 | 1 | 1 |
| Inorganic filler (SS-10) (phr) | 30 | 30 | 30 |
| Dk/Df @ 10 GHZ | 3.07/ | 2.96/ | 3.055/ |
| | 0.0019 | 0.0016 | 0.0016 |

TABLE 3

| Examples | | | E4 | E5 | E6 |
|---|---|---|---|---|---|
| Hydrocarbon | HC 3(phr) | | 100 | 0 | 0 |
| resin (H) | HC 4(phr) | | 0 | 100 | 0 |
| | HC 5(phr) | | 0 | 0 | 100 |
| styrene- | First | Ricon100(phr) | 0 | 0 | 0 |
| based | styrene- | SBS-L(phr) | 14.7 | 14.7 | 14.7 |
| polymer (S) | based | | | | |
| | copolymer | | | | |
| | Second | SBS-2(phr) | 6.3 | 6.3 | 6.3 |
| | styrene- | | | | |
| | based | | | | |
| | copolymer | | | | |

| | | | |
|---|---|---|---|
| Ratio of H/S | 100/21 | 100/21 | 100/21 |
| crosslinking aid (DVB) (phr) | 9 | 9 | 9 |
| Initiator (PERBUTYL P) (phr) | 1 | 1 | 1 |
| Inorganic filler (SS-10) (phr) | 30 | 30 | 30 |
| Dk/Df @ 10 GHZ | 3.12/ | 3.08/ | 3.41/ |
| | 0.0018 | 0.0017 | 0.0020 |

TABLE 4

| Examples | | | E7 | E8 | E9 |
|---|---|---|---|---|---|
| Hydrocarbon | HC 4(phr) | | 100 | 100 | 100 |
| resin (H) | | | | | |
| styrene- | First | Ricon100(phr) | 0 | 0 | 0 |
| based | styrene- | SBS-L(phr) | 17 | 10.5 | 6 |
| polymer (S) | based | | | | |
| | copolymer | | | | |
| | Second | SBS-2(phr) | 4 | 10.5 | 15 |
| | styrene- | | | | |
| | based | | | | |
| | copolymer | | | | |

| | | | |
|---|---|---|---|
| Ratio of H/S | 100/21 | 100/21 | 100/21 |
| crosslinking aid (DVB) (phr) | 9 | 9 | 9 |
| Initiator (PERBUTYL P) (phr) | 1 | 1 | 1 |
| Inorganic filler (SS-10) (phr) | 30 | 30 | 30 |
| Dk/Df @ 10 GHZ | 2.93/ | 2.85/ | 2.73/ |
| | 0.0017 | 0.0017 | 0.0017 |

TABLE 5

| Examples | | | E10 | E11 |
|---|---|---|---|---|
| Hydrocarbon | HC 4(phr) | | 100 | 100 |
| resin (H) | | | | |
| styrene-based | First | Ricon100(phr) | 0 | 0 |
| polymer (S) | styrene- | SBS-L(phr) | 35 | 10.5 |
| | based | | | |
| | copolymer | | | |
| | Second | SBS-1(phr) | 0 | 10.5 |
| | styrene- | SBS-2(phr) | 15 | 0 |
| | based | | | |
| | copolymer | | | |

| | | |
|---|---|---|
| Ratio of H/S (weight ratio) | 100/50 | 100/21 |
| crosslinking aid (DVB) (phr) | 9 | 9 |
| Initiator (PERBUTYL P) (phr) | 1 | 1 |
| Inorganic filler (SS-10) (phr) | 30 | 30 |
| Dk/Df @ 10 GHZ | 3.11/0.0020 | 2.90/0.0016 |

TABLE 6

| Examples | | | E12 | E13 |
|---|---|---|---|---|
| Hydrocarbon | HC 4(phr) | | 100 | 100 |
| resin (H) | | | | |
| styrene-based | First | Ricon100(phr) | 0 | 0 |
| polymer (S) | styrene- | SBS-L(phr) | 14.7 | 24.5 |
| | based | | | |
| | copolymer | | | |
| | Second | SBS-1(phr) | 0 | 0 |
| | styrene- | SBS-2(phr) | 6.3 | 10.5 |
| | based | | | |
| | copolymer | | | |

| | | |
|---|---|---|
| Ratio of H/S (weight ratio) | 100/21 | 100/35 |
| crosslinking aid (DVB) (phr) | 9 | 9 |
| Initiator (PERBUTYL P) (phr) | 1 | 1 |
| Inorganic filler (SS-10) (phr) | 30 | 30 |
| Dk/Df @ 10 GHZ | 2.85/0.0017 | 2.893/0.0018 |

TABLE 7

| Comparative Example | | | C1 | C2 |
|---|---|---|---|---|
| Hydrocarbon | HC 4(phr) | | 100 | 100 |
| resin (H) | | | | |
| styrene-based | First | Ricon100(phr) | 0 | 35 |
| polymer (S) | styrene- | SBS-L(phr) | 0 | 0 |
| | based | | | |
| | copolymer | | | |
| | Second | SBS-2(phr) | 21 | 0 |
| | styrene- | | | |
| | based | | | |
| | copolymer | | | |

| Ratio of H/S (weight ratio) | 100/21 | 100/35 |
|---|---|---|
| crosslinking aid (DVB) (phr) | 9 | 9 |
| Initiator (PERBUTYL P) (phr) | 1 | 1 |
| Inorganic filler (SS-10) (phr) | 30 | 30 |
| Dk/Df @ 10 GHZ | Can not be | 3.2/0.0021 |
| | measured | |

### [Peel Strength Test]

Four glass fiber cloth (Asahi 2116, Dk/Df=3.3/0.0030@10 GHz) were immersed in the resin varnishes of Examples E7-E13 and Comparative Examples C1 and C2, and baked at 160° C. for 10 minutes to form 4 polymer layers of Examples E7-E13 and Comparative Examples C1 and C2 respectively. The 4 polymer layers are laminated with copper foil layers. The copper foil layers were placed between the 4 polymer layers. The copper foil layers and the polymer layers were pressed together to form laminate structures of Examples E7-E13 and Comparative Examples C1 and C2 respectively.

Peel strengths of the laminated structures of Examples E7-E13 and Comparative Examples C1 and C2 were measured by a tensile testing device (SHIMADZU AG-Xplus, test conditions: test speed 50.8 mm/min, test length: 20 mm), and results are shown in Table 8 below.

### [Glass Transition Temperatures (Tg) Measurement]

Two glass fiber cloths (Asahi 2116, Dk/Df=3.3/0.0030@10 GHz) were immersed in the resin varnishes of Examples E7-E13 and Comparative Examples C1 and C2, and baked at 160-170° C. for 5-15 minutes to form 2 polymer layers of Examples E7-E13 and Comparative Examples C1 and C2 respectively. The 2 polymer layers were laminated with a copper foil. A copper foil was placed between the 2 polymer layers. The copper foil and the polymer layers are pressed together to form laminate plates of Examples E7-E13 and Comparative Examples C1 and C2 respectively.

The glass transition temperatures (Tg) of the laminate plates of Examples E7-E13 and Comparative Examples C1 and C2 were measured by dynamic mechanical analysis (DMA, TA/Q800) using a test frequency of 1 Hz, under following test conditions: heating from 25° C. to 270° C. and a heating rate of 3° C./min. The glass transition temperatures (Tg) thereof were obtained from tan Delta peaks in a DMA charts, and results are shown in Table 8 below.

TABLE 8

| | | Glass transition |
|---|---|---|
| | Peel strength (lbf/in) | temperatures (° C.) |
| Example E7 | 2.6 | 147.8 |
| Example E8 | 2.7 | 144.4 |
| Example E9 | 2.5 | 143.1 |
| Example E10 | 1.61 | 147.2 |
| Example E11 | 2.0 | 147.1 |
| Example E12 | 2.7 | 144.4 |
| Example E13 | 1.6 | 143.3 |
| Comparative | Can not be measured | Can not be measured |
| Example C1 | | |
| Comparative | 1.9 | 145.5 |
| Example C2 | | |

From the above results, it can be seen that Comparative Example C1 could not provide measurable results due to the problems of the impregnation processability during the preparation of the prepreg.

As can be seen from Tables 2-7, after being baked at 160° C., the dielectric loss tangents (Df) of the metal foil laminated boards of Examples E1-E13 are lower than those of Comparative Examples C2 and the dielectric loss tangents (Df) of the metal foil laminated boards of Examples E1-E13 are all lower than or equal to 0.0020. That is, by including the prepregs manufactured from the resin varnish including the polymer composite of the present disclosure, the metal foil laminated boards would have lower dielectric loss tangents (Df). The resin varnish (i.e. the low dielectric resin composition of the present disclosure) including the polymer composite of the present disclosure shows excellent dielectric property and/or thermal property.

As can be seen from Table 8, it can be seen that the lower the Ratio of H/S of the resin varnish (i.e. the low dielectric resin composition of the present disclosure), the lower the peel strength. Specifically, the laminated structures of Example E10 has a lower Ratio of H/S (100/50) of the resin varnish and a lower peel strength (1.61 lbf/in). Furthermore, as can be seen from Table 8, it can be seen that the laminated structure of Example E11 has a lower peel strength (2.0 lbf/in) than the laminated structure of Example E8. It indicates that a resin varnish containing a second styrene-based copolymer having a weight average molecular weight of less than 80,000 Da and a viscosity of less than 521.4 Pa·s has a better peel strength. Therefore, preferably, in some embodiments, the Ratio of H/S of the low dielectric resin composition is greater than 100/50, preferably greater than 100/35 to 100/10. In some embodiments, the weight average molecular weight of the second styrene-based copolymer is preferably lower than 80,000 g/mol, preferably in the range of 40,000 to 60,000. In some embodiments, the viscosity of the second styrene-based copolymer is preferably less than 521.4 Pa·s, preferably in the range of 114.8 Pa·s to 327.4 Pa·s. Therefore, in addition to excellent thermal stability and electrical performance, the metal foil laminated board including the prepreg manufactured from the low dielectric resin composition of the present disclosure can also have high peel strength and good reliability.

According to the various tests mentioned above, it can be seen that the low dielectric resin composition of the present disclosure or a low dielectric resin composition including the polymer composite of the present disclosure has good electrical performance. The metal foil laminated board or the prepreg manufactured from the low dielectric resin composition of the present disclosure or a low dielectric resin composition including the polymer composite of the present disclosure will have good electrical performance. In some embodiments, the low dielectric resin composition of the present disclosure or a low dielectric resin composition including the polymer composite of the present disclosure has good processability. The low dielectric resin composition of the present disclosure or a low dielectric resin composition including the polymer composite of the present disclosure still maintain good electrical properties after a heating process and/or a hot pressing process, and are cost-effective. In some embodiments, the metal foil laminated board or the prepreg manufactured from the low dielectric resin composition of the present disclosure or a low dielectric resin composition including the polymer composite of the present disclosure will has good thermal properties and/or mechanical properties.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

1. A polymer composite for preparing a low dielectric resin composition, comprising:
a first styrene-based copolymer having a weight average molecular weight that is lower than 20,000 g/mol; and
a second styrene-based copolymer having a weight average molecular weight that is higher than 20,000 g/mol,
wherein the weight ratio of the first styrene-based copolymer to the second styrene-based copolymer is from 5/95 to 95/5, and the low dielectric resin composition has a dielectric loss tangent (Df) that is less than or equal to 0.00200.

2. A polymer composite for preparing a low dielectric resin composition, comprising:
a first styrene-based copolymer, which is liquid at 25° C.; and
a second styrene-based copolymer, which is solid at 25° C.,
wherein the weight ratio of the first styrene-based copolymer to the second styrene-based copolymer is from 5/95 to 95/5, and the low dielectric resin composition has a dielectric loss tangent (Df) that is less than or equal to 0.00200.

3. The polymer composite of claim 2, wherein the first styrene-based copolymer has a weight average molecular weight that is lower than 10,000 g/mol.

4. The polymer composite of claim 2, wherein the first styrene-based copolymer is a styrene block copolymer.

5. The polymer composite of claim 2, wherein the first styrene-based copolymer is a styrene-butadiene-styrene tri-block copolymer (SBS), and a molar ratio of 1,2-bonding structures to the 1,4-bonding structures comprised in butadiene blocks of the styrene-butadiene-styrene tri-block copolymer (SBS) is 3:1 to 7:1.

6. The polymer composite of claim 2, wherein the second styrene-based copolymer is a styrene butadiene styrene tri-block copolymer (SBS) having a weight average molecular weight that is lower than 80,000 g/mol.

7. The polymer composite of claim 6, wherein the second styrene-based copolymer has a weight average molecular weight of 40,000 to 60,000.

8. The polymer composite of claim 2, wherein the second styrene-based copolymer has a viscosity within a range of 114.8 Pas to 327.4 Pa·s.

9. The polymer composite of claim 2, wherein the weight ratio of the first styrene-based copolymer to the second styrene-based copolymer is from 25/75 to 80/20.

10. A method of using a polymer composite, comprising:
using a polymer composite to form a mixture including a hydrocarbon resin for manufacturing a metal foil laminated board, wherein the polymer composite comprises:
a first styrene-based copolymer having a weight average molecular weight that is lower than 20,000 g/mol; and
a second styrene-based copolymer having a weight average molecular weight that is higher than 20,000 g/mol,
wherein the weight ratio of the first styrene-based copolymer to the second styrene-based copolymer is from 5/95 to 95/5, and the metal foil laminated board has a dielectric loss tangent (Df) that is less than or equal to 0.00200.

11. A low dielectric resin composition, comprising:
a hydrocarbon resin;
a first styrene-based copolymer having a weight average molecular weight that is lower than 20,000 g/mol; and
a second styrene-based copolymer having a weight average molecular weight that is higher than 20,000 g/mol.

12. A low dielectric resin composition, comprising:
a hydrocarbon resin;
a first styrene-based copolymer, which is liquid at 25° C.; and
a second styrene-based copolymer, which is solid at 25° C.

13. The low dielectric resin composition of claim 12, wherein the hydrocarbon resin comprises:
0-40 mol % of repeating units (A), which are derived from a bridged ring monomer compound;
15-92 mol % of repeating units (B), which are derived from a mono vinyl aromatic compound; and
8-80 mol % of repeating units (C), which are derived from a divinyl aromatic compound.

14. The low dielectric resin composition of claim 12, wherein the hydrocarbon resin has a hydrogen atom content in the reactive double bonds in the range of greater than or equal to 2.3% and less than 6.6%.

15. The low dielectric resin composition of claim 12, wherein the low dielectric resin composition comprises more than 53 wt % of the hydrocarbon resin based on the total weight of the low dielectric resin composition.

16. The low dielectric resin composition of claim 12, wherein the weight ratio of the hydrocarbon resin to the sum of the first styrene-based copolymer and the second styrene-based copolymer is in a range of greater than 100/50 and less than or equal to 100/10.

17. The low dielectric resin composition of claim 12, further comprising an additive, wherein the additive is selected from a group consisting of an initiator, a flame retardant, an inorganic filler, a crosslinking aid, and any combination thereof.

18. A prepreg is manufactured from the low dielectric resin composition comprising the polymer composite of claim 2.

19. The prepreg of claim 18 is prepared using a method comprising the following steps:
providing a resin varnish containing the low dielectric resin composition;
forming a mixture by dipping a fibrous base material into the resin varnish; and
heating the mixture to 100 to 180° C. to obtain the prepreg in a semi-cured state.

20. The prepreg of claim 19, wherein the fibrous base material is a glass fiber cloth having a dielectric loss tangent (Df) that is less than or equal to 0.0030.

21. A metal foil laminated board, comprising the prepreg of claim 18.
